(19) United States
(12) Patent Application Publication
(10) Pub. No.: US 2008/0083924 A1
(43) Pub. Date: Apr. 10, 2008

(54) THIN FILM TRANSISTOR HAVING CHALCOGENIDE LAYER AND METHOD OF FABRICATING THE THIN FILM TRANSISTOR

(76) Inventors: Kibong SONG, Daejeon-city (KR); Doo-Hee CHO, Daejeon-city (KR); Kyeongam KIM, Daejeon-city (KR); Sang Su LEE, Daejeon-city (KR)

Correspondence Address: LADAS & PARRY LLP, 224 SOUTH MICHIGAN AVENUE, SUITE 1600, CHICAGO, IL, 60604, US

(21) Appl. No.: 11/869,175

(22) Filed: Oct. 9, 2007

(30) Foreign Application Priority Data
Oct. 9, 2006 (KR) 10-2006-0098099
Apr. 18, 2007 (KR) 10-2007-0037955

(51) Int. Cl. H01L 31/0272; H01L 21/12; H01L 29/04

(52) U.S. Cl. 257/55; 257/57; 438/102; 257/E29.003; 257/E21.075; 257/E31.009

(57) ABSTRACT

Provided are a thin film transistor (TFT) having a chalcogenide layer and a method of fabricating the TFT. The TFT includes an amorphous chalcogenide layer, a crystalline chalcogenide layer, source and drain electrodes, and a gate electrode. The amorphous chalcogenide layer forms a channel layer. The crystalline chalcogenide layer is formed on both sides of the amorphous layer to form source and drain regions. The source and drain electrodes are formed on both sides of the amorphous chalcogenide layer and connected to the source and drain regions of the crystalline chalcogenide layer, respectively. The gate electrode is formed above or under the channel layer with a gate insulation layer being interposed between the channel layer and the gate electrode. Therefore, the TFT can include an optical TFT structure using the chalcogenide layers as an optical conductive layer and/or an electric TFT providing diode rectification using the chalcogenide layers.

### CROSS-REFERENCE TO RELATED PATENT APPLICATION

This application claims the benefit of Korean Patent Application No. 10-2006-0098099, filed on Oct. 9, 2006 and Korean Patent Application No. 10-2007-0037955, filed on Apr. 18, 2007 in the Korean Intellectual Property Office, the disclosures of which are incorporated herein in their entirety by reference.

### BACKGROUND OF THE INVENTION

1. Field of the Invention

The present invention relates to a thin film transistor and a method of fabricating the thin film transistor, and more particularly, to a thin film transistor including a chalcogenide layer and a method of fabricating the thin film transistor.

2. Description of the Related Art

Thin film transistors are used for various purposes. For example, thin film transistors are used in a liquid crystal display or an image sensor. Thin film transistors are usually fabricated through a complementary metal oxide semiconductor (CMOS) process.

FIG. 1 illustrates a conventional thin film transistor fabricated using a CMOS process.

Referring to FIG. 1, an amorphous silicon layer 105 is formed on a silicon substrate 100 doped with an impurity. Source and drain ohmic contacts 115 and 110 are formed on both sides of the amorphous silicon layer 105. The source and drain ohmic contacts 115 and 110 are formed by implanting impurity ions in predetermined regions of the amorphous silicon layer 105. Source and drain electrodes 125 and 120 are formed at the source and drain ohmic contacts 115 and 110, respectively. A gate insulation layer 130 is formed on the amorphous silicon layer 105, the source and drain ohmic contacts 115 and 110, and the source and drain electrodes 125 and 120. The gate insulation layer 130 is formed of a silicon oxide. A gate electrode 135 is formed on the gate insulation layer 130 using a metal.

However, when the thin film transistor of FIG. 1 is used as a photo thin film transistor, the thin film transistor of FIG. 1 may operate at low efficiency since the amorphous silicon layer 105 has low photoconductivity.

Since the thin film transistor of FIG. 1 is fabricated using a CMOS process, a high processing temperature, for example, 500° C. to 1000° C., is required. Furthermore, the silicon substrate 100, which is used in the CMOS process for forming the thin film transistor of FIG. 1, is very expensive, and ion implantation is required to form the source and drain ohmic contacts 115 and 110. Therefore, the manufacturing costs for fabricating the thin film transistor of FIG. 1 through the CMOS process are high.

### SUMMARY OF THE INVENTION

The present invention provides a thin film transistor (TFT) including a chalcogenide layer having high optical conductivity (high photoconductivity).

The present invention also provides a method of fabricating a TFT including a chalcogenide layer having high optical conductivity without using a high-temperature and very expensive complementary metal oxide semiconductor (CMOS) process.

According to an aspect of the present invention, there is provided a TFT including an amorphous chalcogenide layer forming a channel layer and a crystalline chalcogenide layer formed on both sides of the amorphous chalcogenide layer in order to form a source region and a drain region. The TFT further includes source and drain electrodes and a gate electrode. The source and drain electrodes are formed on both sides of the amorphous chalcogenide layer and connected to the source and drain regions of the crystalline chalcogenide layer, respectively, and the gate electrode is formed above or under the channel layer with a gate insulation layer being interposed between the channel layer and the gate electrode.

According to another aspect of the present invention, there is provided a TFT including a channel layer formed of an amorphous chalcogenide layer, and source and drain regions respectively formed on both sides of the channel layer using a crystalline chalcogenide layer. The TFT further includes source and drain electrodes and a gate electrode. The source and drain electrodes are formed on both sides of the amorphous chalcogenide layer and connected to the source and drain regions, respectively, and the gate electrode formed above or under the channel layer with an gate insulation layer being interposed between the channel layer and the gate electrode.

The chalcogenide layer forming the channel layer, the source region, and the drain region may be used as an optical conductive layer generating an optical current by absorbing light, and the gate electrode may be used to turn on/off the optical current, so that the TFT is used as an optical TFT. The TFT may be used as an electric TFT providing diode rectification using a potential barrier between the amorphous chalcogenide layer forming the channel layer and the crystalline chalcogenide layer forming the source and drain regions.

According to another aspect of the present invention, there is provided a method of fabricating a TFT, the method including forming an amorphous chalcogenide layer as a channel layer. Both sides of the amorphous chalcogenide layer are changed into a crystalline chalcogenide layer to form source and drain regions. Source and drain electrodes are formed on the crystalline chalcogenide layer forming the source and drains regions. A gate electrode is formed above or under the channel layer of the amorphous chalcogenide layer with a gate insulation layer being interposed between the gate electrode and the channel layer.

Therefore, according to the present invention, an optical TFT can be formed using a chalcogenide layer as an optical conductive layer. In addition, an electric TFT can be formed using amorphous and crystalline chalcogenide layers in order to provide diode rectification.

### BRIEF DESCRIPTION OF THE DRAWINGS

The above and other features and advantages of the present invention will become more apparent by describing in detail exemplary embodiments thereof with reference to the attached drawings in which:

FIG. 1 illustrates a conventional thin film transistor fabricated using a complementary metal oxide semiconductor (CMOS) process;

FIG. 2 is a cross-sectional view illustrating a photo TFT according to an embodiment of the present invention;

FIG. 3 is a cross-sectional view for explaining the concept and structure of an electric TFT according to an embodiment of the present invention;

FIGS. 4 and 5 illustrate the energy band diagrams of a crystalline chalcogenide layer and an amorphous chalcogenide layer before and after the crystalline chalcogenide layer contacts the amorphous chalcogenide layer as shown in FIG. 3;

FIG. 6 is a graph showing diode rectification characteristics of the electric TFT of FIG. 3;

FIG. 7 is a cross-sectional view illustrating a TFT according to an embodiment of the present invention;

FIG. 8 is a cross-sectional view illustrating a TFT according to another embodiment of the present invention;

FIGS. 9 through 16 are cross-sectional views for explaining a method of fabricating the TFT of FIG. 8 according to an embodiment of the present invention; and

FIG. 17 is a graph illustrating a relationship between a gate current and a gate voltage of the TFT of FIG. 16.

### DETAILED DESCRIPTION OF THE INVENTION

The present invention will now be described more fully with reference to the accompanying drawings, in which exemplary embodiments of the invention are shown. The invention may, however, be embodied in many different forms and should not be construed as being limited to the embodiments set forth herein; rather, these embodiments are provided so that this disclosure will be thorough and complete, and will fully convey the concept of the invention to those skilled in the art. In the drawings, the thicknesses of layers and regions are exaggerated for clarity.

Chalcogenide is considered to be the next generation of materials for data storage devices or non-volatile memory devices. In the present invention, a chalcogenide layer is used as a channel layer, an optical conductive layer, and source and drain regions of a thin film transistor. The chalcogenide layer can be formed of GeTe—Sb₂Te₃ or Ge₂Sb₂Te₅ (collectively called GST); however, the present invention is not limited thereto.

In the present invention, the chalcogenide layer can be used as an optical conductive layer of a photo thin film transistor (TFT) since the chalcogenide layer has a high photoconductivity. Furthermore, the phase of the chalcogenide layer changes between an amorphous phase and a crystalline phase using thermal energy or laser beam. Hence, the present invention provides an electric TFT capable of diode rectification using a potential barrier occurring due to a charge concentration difference between an amorphous chalcogenide layer and a crystalline chalcogenide layer. Also, the present invention provides a TFT including a photo TFT and/or an electric TFT using a chalcogenide layer. In addition, the TFT of the present invention can be formed on a glass substrate through a low-temperature process with lower costs.

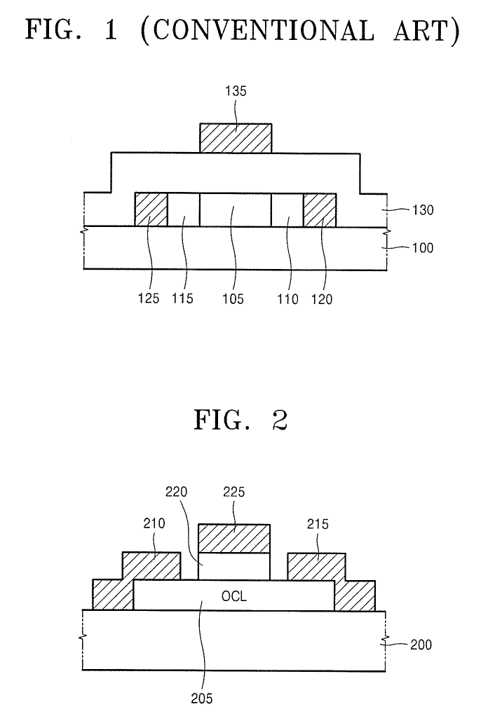

FIG. 2 is a cross-sectional view illustrating a photo TFT according to an embodiment of the present invention.

Referring to FIG. 2, a chalcogenide layer 205 is formed on a substrate 200 such as a glass substrate. The chalcogenide layer 205 is an optical conductive layer (OCL). The substrate 200 can be a glass substrate since elements of the photo TFT are formed of materials not requiring a high-temperature treatment. The glass substrate is suitable for an optical device since the glass substrate is transparent.

The chalcogenide layer 205 has high optical conductivity. The chalcogenide layer 205 may be formed of a GST layer. The chalcogenide layer 205 is sensitive to light and generates an optical current by absorbing light. The chalcogenide layer 205 is a thin layer whose state can change between an amorphous phase and a crystalline phase according to the intensity and period of heat or laser radiation. The chalcogenide layer 205 may be an amorphous thin layer formed by initial deposition.

A source electrode 210 and a drain electrode 215 are formed on the substrate 200 and are connected to the chalcogenide layer 205. The source electrode 210 and the drain electrode 215 are formed of a metal such as gold or aluminum. When the chalcogenide layer 205 absorbs light, the chalcogenide layer 205 generates a current, and the current flows through the source and drain electrodes 210 and 215.

A gate insulation layer 220 is formed on the chalcogenide layer 205. The gate insulation layer 220 is formed of a chalcogenide-based insulation material. For example, the gate insulation layer 220 can be formed of As₂S₃, an organic polymer such as poly methyl methacrylate (PMMA), a silicon oxide, or a silicon insulation material. The PPMA is a transparent material. The gate insulation layer 220 makes tight contact with the chalcogenide layer 205 and prevents the chalcogenide layer from changing in properties during a manufacturing process of the photo TFT.

A gate electrode 225 is formed on the gate insulation layer 220. The gate electrode 225 is used for turning on or off the optical current of the chalcogenide layer 205. The gate electrode 225 is formed of a metal such as gold, aluminum, or chrome. Although the gate electrode 225, the source electrode 210, and the drain electrode 215 are formed of a non-transparent metal in the current embodiment, the gate electrode 225, the source electrode 210, and the drain electrode 215 can be formed of a transparent metal. In FIG. 2, the gate insulation layer 220 and the gate electrode 225 are formed on the chalcogenide layer 205 as a top gate structure. However, the gate insulation layer 220 and the gate electrode 225 can be formed under the chalcogenide layer 205 as a bottom gate structure.

The TFT of FIG. 2 is a photo TFT having a switching function based on the chalcogenide layer 205. In addition to the photo TFT, the present invention also provides an electric TFT having a diode rectification function based on a chalcogenide layer. Hereinafter, a TFT structure such as a photo TFT and an electric TFT, and a method of forming the TFT structure will be described in detail.

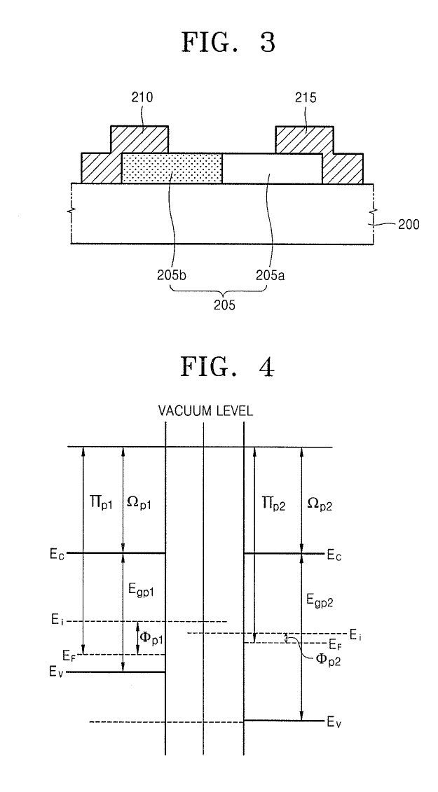

FIG. 3 is a cross-sectional view for explaining the concept and structure of an electric TFT according to an embodiment of the present invention. In FIGS. 2 and 3, like reference numerals denote like elements.

Referring to FIG. 3, a chalcogenide layer 205 is formed on a substrate 200 such as a glass substrate. The chalcogenide layer 205 includes a crystalline chalcogenide layer 205b and an amorphous chalcogenide layer 205a. The crystalline chalcogenide layer 205b is formed at one side of the chalcogenide layer 205, and the amorphous chalcogenide layer 205a is formed at the other side of the chalcogenide layer 205. The crystalline chalcogenide layer 205b is formed by changing a chalcogenide layer formed on the substrate 200 from an amorphous phase into a crystalline phase using heat or laser radiation. A source electrode 210 and a drain electrode 215 are formed on the crystalline chalcogenide layer 205b and the amorphous chalcogenide layer 205a, respectively.

In the electric TFT, the crystalline chalcogenide layer 205b and the amorphous chalcogenide layer 205a are in contact with each other. Hence, the electric TFT can have a diode rectification function according to a potential barrier between the crystalline chalcogenide layer 205b and the amorphous chalcogenide layer 205a. The diode rectification function of the electric TFT will be described later in more detail.

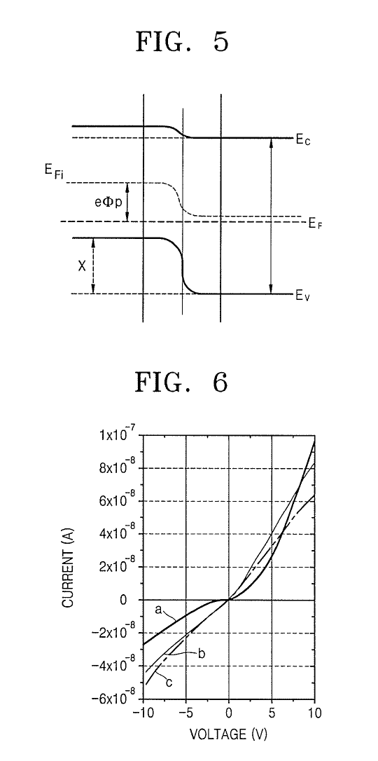

FIGS. 4 and 5 illustrate the energy band diagrams of a crystalline chalcogenide layer and an amorphous chalcogenide layer before and after the crystalline chalcogenide layer contacts the amorphous chalcogenide layer like in the case of FIG. 3.

Referring to FIG. 4, the energy bands of a crystalline chalcogenide layer are shown on the left side, and the energy bands of an amorphous chalcogenide layer are shown on the right side. A chalcogenide, such as GST, can be formed into only a p-type semiconductor due to the atomic structure of the chalcogenide. In an amorphous condition, p-type majority carriers are dependent on a lone pair electron state. That is, the amorphous chalcogenide layer exhibits p-type semiconductor characteristics due to the lone pair electron state. The amorphous chalcogenide layer is a p-type semiconductor layer of which Fermi level E_{F} is closed to an intrinsic level Eᵢ. A charge concentration (carrier concentration) difference between the Fermi level E_{F} and the intrinsic level Eᵢ is very small (φₚ₂). In the amorphous chalcogenide layer, a band gap E_{gp2} between a valence band E_{V} and a conduction band E_{C} is 0.7 eV.

The crystalline chalcogenide layer does not have a lone pair electron state. However, the crystalline chalcogenide layer exhibits p-type semiconductor characteristics due to majority carriers caused by a vacancy state of a periodic crystal atom structure. A charge concentration of the crystalline chalcogenide layer is large due to the vacancy state. In the crystalline chalcogenide layer, a Fermi level E_{F} is close a valence band E_{V}, and a charge concentration (carrier concentration) different between an intrinsic level Eᵢ and the Fermi level E_{F} is larger (φₚ₁). In the amorphous chalcogenide layer, a band gap E_{gp1} between the valence band E_{V} and a conduction band E_{C} is 0.5 eV. In FIG. 4, πₚ₁ and Ωₚ₁ denote a work function and an electron affinity of the crystalline chalcogenide layer, respectively, and πₚ₂ and Ωₚ₂ denote a work function and an electron affinity of the amorphous chalcogenide layer, respectively.

FIG. 5 is an energy band diagram of the crystalline chalcogenide layer and the amorphous chalcogenide layer when the crystalline chalcogenide layer and amorphous chalcogenide layer contact each other like in the case of FIG. 3. A potential barrier X between the crystalline chalcogenide layer and the amorphous chalcogenide layer can be expressed by Equation 1 below.
X=(ΔE_{gp}/2)+KbTln(P1/P2)−Δφₚ [Equation 1]

where ΔE_{gp}=E_{gp2}−E_{gp1}, Δφₚ=φₚ₂−φₚ₁, P1 and P2 denote carrier concentrations, T denotes an absolute temperature, and Kb denotes the Boltzmann constant.

Referring to FIG. 5, a TFT as shown in FIG. 3 can have a diode rectification function owning to the potential barrier X confining majority carriers (holes). In the structure shown in FIG. 3, since the potential barrier X is not high for electrons, a noise current can flow somewhat. In FIG. 5, E_{Fi} denotes a line connecting intrinsic levels of the amorphous chalcogenide layer and the crystalline chalcogenide layer, and ₑφₚ denotes a potential difference between a Fermi level E_{F} and the E_{Fi} of the crystalline chalcogenide layer.

FIG. 6 is a graph showing diode rectification characteristics of the electric TFT of FIG. 3.

Referring to FIG. 6, diode rectification characteristics are measured using the electric TFT illustrated in FIG. 3. Reference characteristics “c”, “b”, and “a” denote diode rectification characteristic curves of the electric TFT when the resistance of the crystalline chalcogenide layer 205b is 100 Kohm, 10 Kohm, and 2.5 Kohm, respectively. As shown in FIG. 6, the diode rectification characteristics of the electric TFT are dependent on the resistance of the crystalline chalcogenide layer 205b. As the resistance of the crystalline chalcogenide layer 205b decreases, the diode rectification characteristics of the electric TFT improves. Therefore, it can be understood that the diode rectification characteristics of the electric TFT can be improved by perfectly dividing the chalcogenide layer 205 into the crystalline chalcogenide layer 205b and the amorphous chalcogenide layer 205a.

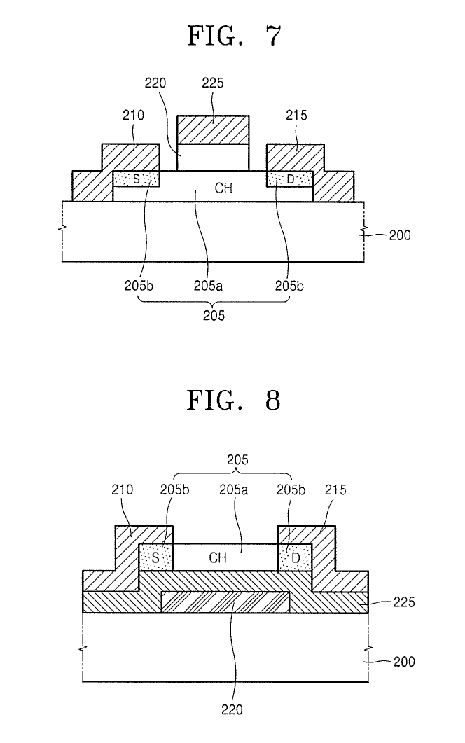

FIG. 7 is a cross-sectional view illustrating a TFT according to an embodiment of the present invention.

In the current embodiment, the TFT includes an electric TFT structure providing diode rectification and a photo TFT structure. The TFT is a top gate type TFT.

Referring to FIG. 7, an amorphous chalcogenide layer 205a is formed on a substrate 200 such as a glass substrate. The amorphous chalcogenide layer 205a forms a channel layer CH. A crystalline chalcogenide layer 205b is formed at both sides of the amorphous chalcogenide layer 205a to form source and drain regions S and D. The amorphous chalcogenide layer 205a and the crystalline chalcogenide layer 205b form a chalcogenide layer 205 on the substrate 200. After the amorphous chalcogenide layer 205a is formed, the crystalline chalcogenide layer 205b is formed by changing both sides of the amorphous chalcogenide layer 205a from an amorphous state to a crystalline state using heat or laser radiation instead of ion implantation.

A source electrode 210 and a drain electrode 215 are formed on both sides of the amorphous chalcogenide layer 205a and are connected to the source and drain regions S and D of the crystalline chalcogenide layer 205b, respectively. A gate insulation layer 220 and a gate electrode 225 are sequentially formed on the channel layer CH of the amorphous chalcogenide layer 205a.

The source electrode 210, the drain electrode 215, the gate insulation layer 220, and the gate electrode 225 are formed of the same materials as presented with reference to FIG. 2. The TFT of FIG. 7 includes a photo TFT structure like the structure of the photo TFT illustrated in FIG. 2. In other words, the channel layer CH, the source region S, and the drain region D of the chalcogenide layer 205 function as an optical conductive layer producing an optical current by absorbing light. The gate electrode 225 can be used to turn on and off the optical current. In addition, the TFT of FIG. 7 includes an electric TFT structure like the structure of the electric TFT illustrated with reference to FIGS. 3 through 6. The electric TFT structure of the TFT of FIG. 7 provides a diode rectification function owing to a potential barrier between the amorphous chalcogenide layer 205a and the crystalline chalcogenide layer 205b. The potential barrier is formed by a charge concentration difference caused by a lone pair electron state of the amorphous chalcogenide layer 205a and a vacancy state of the crystalline chalcogenide layer 205b.

FIG. 8 is a cross-sectional view illustrating a TFT according to another embodiment of the present invention.

The TFT of the current embodiment is a bottom gate type TFT. The TFT of the current embodiment has the same structure as the TFT illustrated in FIG. 7 except that a gate insulation layer 225 and a gate electrode 220 are formed under a chalcogenide layer 205. In FIGS. 7 and 8, like reference numerals denotes like elements.

Referring to FIG. 8, the gate electrode 220 is formed on a substrate 200 such as a glass substrate. The gate insulation layer 225 is formed on the substrate 200 including the gate electrode 220. An amorphous chalcogenide layer 205a is formed on the gate insulation layer 225 above the gate electrode 220. The amorphous chalcogenide layer 205a forms a channel layer CH. A crystalline chalcogenide layer 205b is formed at both sides of the amorphous chalcogenide layer 205a to form a source region S and a drain region D.

After the amorphous chalcogenide layer 205a is formed, the crystalline chalcogenide layer 205b is formed by changing both sides of the amorphous chalcogenide layer 205a from an amorphous state to a crystalline state using heat or laser radiation instead of using ion implantation. A source electrode 210 and a drain electrode 215 are formed on both sides of the amorphous chalcogenide layer 205a and are connected to the source and drain regions S and D of the crystalline chalcogenide layer 205b, respectively.

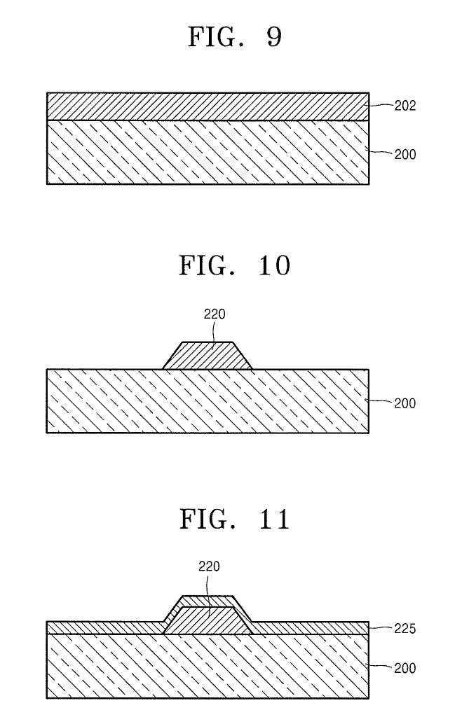

FIGS. 9 through 16 are cross-sectional views for explaining a method of fabricating the TFT of FIG. 8 according to an embodiment of the present invention.

Referring to FIG. 9, a gate electrode metal layer 202 is formed on a substrate 200 such as a glass substrate. In the current embodiment, the gate electrode metal layer 202 is formed of a multi-layer including a 10-nm chrome layer and a 300-nm aluminum layer. The gate electrode metal layer 202 is formed by sputtering. Referring to FIG. 10, the gate electrode metal layer 202 is patterned by photolithography to form a gate electrode 220. The gate electrode 220 has a width of 30 μm.

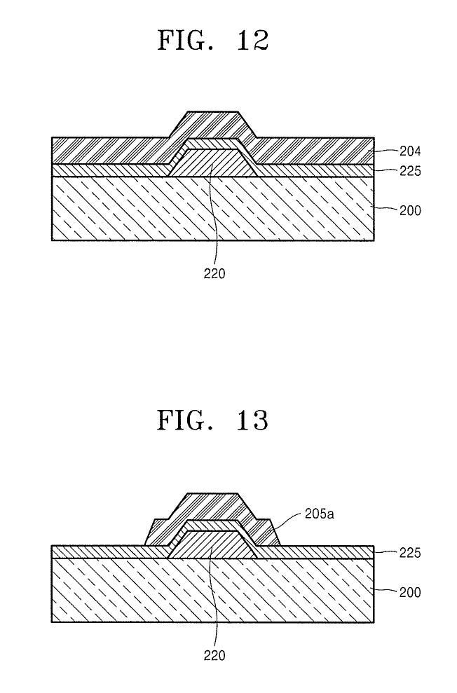

Referring to FIG. 11, a gate insulation layer 225 is formed on the gate electrode 220 and the substrate 200. For example, the gate insulation layer 225 is formed of a silicon oxide by plasma enhanced chemical vapor deposition (PECVD). The gate insulation layer 225 is formed to a thickness of 200 nm. Referring to FIG. 12, an initial amorphous chalcogenide layer 204 is formed on the gate insulation layer 225. The initial amorphous chalcogenide layer 204 is formed of GST by sputtering.

Referring to FIG. 13, the initial amorphous chalcogenide layer 204 is patterned to form an amorphous chalcogenide layer 205a on the gate insulation layer 225 above the gate electrode 220. The initial amorphous chalcogenide layer 204 is patterned by photolithography including wet etching.

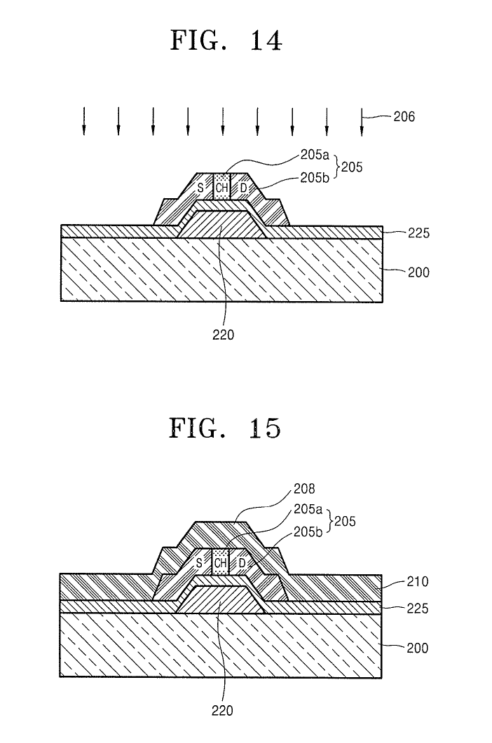

Referring to FIG. 14, laser light is irradiated to both sides of the amorphous chalcogenide layer 205a to form a crystalline chalcogenide layer 205b. Therefore, a chalcogenide layer 205 including the amorphous chalcogenide layer 205a and the crystalline chalcogenide layer 205b is formed on the gate insulation layer 225 about the gate electrode 220. The amorphous chalcogenide layer 205a forms a channel layer CH, and the crystalline chalcogenide layer 205b includes a source region S and a drain region D.

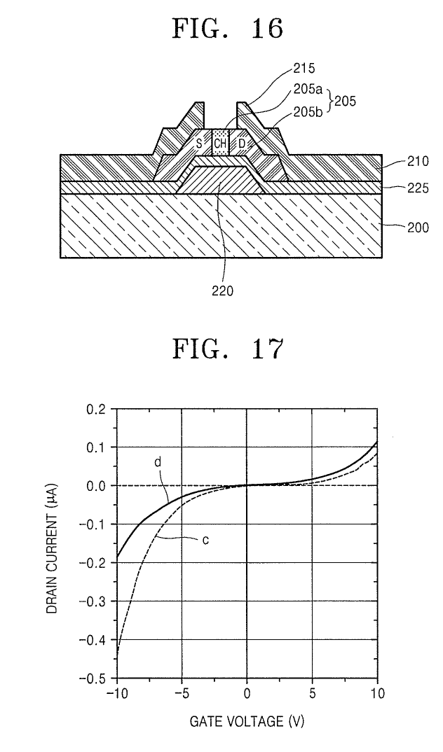

Referring to FIG. 15, a source and drain electrode metal layer 208 is formed on the chalcogenide layer 205 and the gate insulation layer 225. For example, the source and drain electrode metal layer 208 can be formed of gold. The source and drain electrode metal layer 208 is formed on the entire surface of the substrate 200 including the chalcogenide layer 205 and the gate insulation layer 225. The source and drain electrode metal layer 208 is formed by evaporation. Referring to FIG. 16, the source and drain electrode metal layer 208 is patterned to form a source electrode 210 and a drain electrode 215 on the source and drain regions S and D of the crystalline chalcogenide layer 205b. In this was, the fabrication of the TFT is completed.

FIG. 17 is a graph illustrating a relationship between a drain current and a gate voltage of the TFT of FIG. 16.

Referring to FIG. 17, c and d denote drain current versus gate voltage curves when a drain voltage is −14 V and 0 V, respectively. When a gate voltage increases from 0 V, a drain current increases in proportion to the gate voltage. Further, when the gate voltage decreases from 0 V, the drain current decreases in proportion to the gate voltage. That is, each of the curves c and d has the same shape as that of a typical diode rectification characteristic curve. Hence, it can be understood that the TFT of the present invention has a diode rectification function.

As described above, according to the present invention, the TFT includes the chalcogenide layer formed of a chalcogenide-based material having a high optical conductivity as an optical conductive layer. Furthermore, the TFT provides diode rectification using a lone pair electron state of the amorphous chalcogenide layer and a vacancy state of the crystalline chalcogenide layer. In addition, the TFT includes an optical TFT structure and/or an electric TFT structure.

Moreover, the TFT of the present invention can be formed using a glass substrate instead of an expensive silicon substrate. In this case, the TFT can be formed through a low-temperature process using the glass substrate. Furthermore, the TFT can be formed with lower costs since the TFT can be formed without using a CMOS process, and ohmic contacts can be formed without an ion implantation process.

In addition, the TFT can include an optical TFT structure and an electric TFT structure using the chalcogenide layer. Therefore, the TFT can be formed in a compact shape with lower costs for various devices.

While the present invention has been particularly shown and described with reference to exemplary embodiments thereof, it will be understood by those of ordinary skill in the art that various changes in form and details may be made therein without departing from the spirit and scope of the present invention as defined by the following claims.

What is claimed is:

1. A thin film transistor (TFT) comprising:
an amorphous chalcogenide layer forming a channel layer;
a crystalline chalcogenide layer formed on both sides of the amorphous layer to form a source region and a drain region;
source and drain electrodes formed on both sides of the amorphous chalcogenide layer and connected to the source and drain regions of the crystalline chalcogenide layer, respectively; and
a gate electrode formed above or under the channel layer with a gate insulation layer being interposed between the channel layer and the gate electrode.

2. The TFT of claim 1, wherein the amorphous chalcogenide layer and the crystalline chalcogenide layer are formed of Ge—Sb—Te (GST) layers.

3. The TFT of claim 1, wherein the TFT is used as an electric TFT providing diode rectification using a potential barrier between the amorphous chalcogenide layer and the crystalline chalcogenide layer.

4. The TFT of claim 1, wherein the channel layer, the source region, and the drain region are used as an optical conductive layer generating an optical current by absorbing light, and the gate electrode is used to turn on/off the optical current, so that the TFT is used as an optical TFT.

5. The TFT of claim 1, wherein the amorphous chalcogenide layer is formed on a glass substrate.

6. A TFT comprising:
a channel layer formed of an amorphous chalcogenide layer;
source and drain regions respectively formed on both sides of the channel layer using a crystalline chalcogenide layer;
source and drain electrodes formed on both sides of the amorphous chalcogenide layer and connected to the source and drain regions, respectively; and
a gate electrode formed above or under the channel layer with a gate insulation layer being interposed between the channel layer and the gate electrode,
wherein the channel layer, the source region, and the drain region are used as an optical conductive layer generating an optical current by absorbing light, and the gate electrode is used to turn on/off the optical current, so that the TFT is used as an optical TFT, and
the TFT is used as an electric TFT providing diode rectification using a potential barrier between the amorphous chalcogenide layer forming the channel layer and the crystalline chalcogenide layer forming the source and drain regions.

7. The TFT of claim 6, wherein the amorphous chalcogenide layer and the crystalline chalcogenide layer are formed of GST layers.

8. The TFT of claim 6, wherein the potential barrier is formed by a charge concentration difference caused by a vacancy state of the crystalline chalcogenide layer forming the source and drain regions and a lone pair electron state of the amorphous chalcogenide layer forming the channel layer.

9. A method of fabricating a TFT, comprising:
forming an amorphous chalcogenide layer as a channel layer;
changing both sides of the amorphous chalcogenide layer into a crystalline chalcogenide layer to form source and drain regions;
forming source and drain electrodes on the crystalline chalcogenide layer forming the source and drains regions; and
forming a gate electrode above or under the channel layer of the amorphous chalcogenide layer with a gate insulation layer being interposed between the gate electrode and the channel layer.

10. The method of claim 9, wherein the amorphous chalcogenide layer is formed on a glass substrate.

11. The method of claim 9, wherein the amorphous chalcogenide layer and the crystalline chalcogenide layer are formed of a GST layers.

12. The method of claim 9, wherein the changing of both sides of the amorphous chalcogenide layer comprising applying heat or laser radiation to both sides of the amorphous chalcogenide layer.
